(19) United States
(12) Patent Application Publication
(10) Pub. No.: US 2026/0198164 A1
(43) Pub. Date: Jul. 9, 2026

(54) LIGHT-EMITTING BACKPLANE AND DISPLAY APPARATUS

(71) Applicants: Hefei BOE Ruisheng Technology Co., Ltd., Hefei, Anhui, (CN); BOE TECHNOLOGY GROUP CO., LTD., Beijing (CN)

(72) Inventors: Chunjian LIU, Beijing (CN); Jian TIAN, Beijing (CN); Jie LEI, Beijing (CN); Yajun MA, Beijing (CN); Jianying ZHANG, Beijing (CN); Zhen QIU, Beijing (CN)

(21) Appl. No.: 18/867,703

(22) PCT Filed: Sep. 19, 2023
(86) PCT No.: PCT/CN2023/119688

§ 371 Date: Nov. 20, 2024

(51) Int. Cl. H10H 29/85; H10H 29/24; H10H 29/80

(52) U.S. Cl. CPC H10H 29/857; H10H 29/24; H10H 29/942

(57) ABSTRACT

A light-emitting backplane and a display apparatus are provided. The light-emitting backplane includes: a substrate, light-emitting units arranged in a first array; and driving members arranged in a second array; orthographic projections of the first array and the second array on the substrate do not overlap with each other; each driving member include m channels, in the first region, each driving member is electrically connected to m light-emitting units at intersection positions of a rows and b columns in the first array; in the second region, a total number of rows in the first array arranged along the first direction is c, and each of at least some driving members is electrically connected to c×b light-emitting units at intersection positions of c rows of light-emitting units and b columns of light-emitting units, and d light-emitting units adjacent to the c×b light-emitting units along the second direction.

### TECHNICAL FIELD

The present disclosure relates to the field of display technology, and in particular to a light-emitting backplane and a display apparatus.

### BACKGROUND

A mini-LED (mini light-emitting diode) display apparatus may be a display apparatus to which a mini-LED backlight technology is applied (i.e., the mini-LED is used as a backlight source of a liquid crystal display panel), or a display apparatus in which the mini-LED is directly used as a display unit of the display apparatus, and the mini-LED display apparatus can obtain more excellent contrast and brightness by partitioning the backlight, and has a better display quality.

### SUMMARY

In a first aspect, an embodiment of the present disclosure provides a light-emitting backplane, including a display region and a binding side border region, wherein the binding side border region is located on one side of the display region, and the display region includes a first region and a second region sequentially arranged along a first direction away from the binding side border region; wherein the light-emitting backplane includes: a substrate, a plurality of light-emitting units, wherein the plurality of light-emitting units are located on one side of the substrate, and are arranged in a first array along the first direction and a second direction; and a plurality of driving members located on the side of the substrate where the plurality of light-emitting units are located, wherein the plurality of driving members are arranged in a second array along the first direction and the second direction; wherein the first direction and the second direction intersect with each other; orthographic projections of the first array and the second array on the substrate do not overlap with each other; each of the plurality of driving members includes m channels, in the first region, each driving member is electrically connected to m light-emitting units at intersection positions of a rows of light-emitting units sequentially arranged along the first direction and b columns of light-emitting units sequentially arranged along the second direction in the first array, and each driving member is electrically connected to different light-emitting units; in the second region, the total number of rows of light-emitting units in the first array arranged along the first direction is c, and each of at least some driving members is electrically connected to c×b light-emitting units at intersection positions of c rows of light-emitting units arranged sequentially along the first direction and b columns of light-emitting units arranged sequentially along the second direction in the first array, and d light-emitting units adjacent to the c×b light-emitting units along the second direction; and 0<c<a, c×b<m, c×b+d=m, a>1, b>0, m>1, 0<<m, and a, b, c, d, and m are integers.

In some embodiments, the light-emitting backplane further includes a plurality of first wiring lines and a plurality of groups of second wiring lines, which are located on the side of the substrate where the plurality of light-emitting units are located and located on a side of the plurality of light-emitting units and the plurality of driving members close to the substrate; wherein the plurality of first wiring lines and the plurality of groups of second wiring lines are arranged in the same layer; the plurality of first wiring lines are sequentially arranged along the second direction, and extend along the first direction; the plurality of first wiring lines are electrically connected to the plurality of columns of the light-emitting units sequentially arranged along the second direction in the first array in one-to-one correspondence; the plurality of groups of second wiring lines are sequentially arranged along the second direction, and each group of second wiring lines extends along the first direction, and the plurality of groups of second wiring lines are electrically connected to the plurality of columns of the driving members sequentially arranged along the second direction in the second array in one-to-one correspondence.

In some embodiments, a=m and b=1.

In some embodiments, a>1 and b>1.

In some embodiments, one of the plurality of first wiring lines electrically connected to the light-emitting units in the same column and one of the plurality of groups of second wiring lines electrically connected to the driving members in a column are located on two opposite sides of the light-emitting units in the column along the second direction, respectively; an orthographic projection of each driving member on the substrate is located between orthographic projections of the two light-emitting units adjacent to the driving member along the first direction on the substrate; the m channels are electrically connected to different light-emitting units through different first connecting lines, respectively, and the first connecting lines, the plurality of first wiring lines and the plurality of groups of second wiring lines are arranged in the same layer, and orthographic projections of the first connecting lines, the plurality of first wiring lines and the plurality of groups of second wiring lines on the substrate do not overlap with each other.

In some embodiments, the plurality of first wiring lines and the plurality of groups of second wiring lines are arranged alternately in sequence along the second direction.

In some embodiments, any one column of the columns of the driving members sequentially arranged along the second direction is located between two columns of light-emitting units sequentially arranged along the second direction adjacent to the column of the driving members; the m channels are electrically connected to different light-emitting units through different first connecting lines, respectively; and the first connecting lines are located on a side of the plurality of first wiring lines and the plurality of groups of second wiring lines away from the substrate, and on a side of the plurality of light-emitting units and the plurality of driving members close to the substrate, and orthographic projections of the first connecting lines, the plurality of first wiring lines and the plurality of groups of second wiring lines on the substrate at least partially overlap with each other.

In some embodiments, any one group of second wiring lines is located between two first wiring lines adjacent to the group of second wiring lines along the second direction, and orthographic projections of the first wiring line and the corresponding column of light-emitting units electrically connected to the first wiring line on the substrate at least partially overlap with each other.

In some embodiments, in the second region, the first connecting lines extend from the respective channels of each driving member to one side of the second region away from the first region and are electrically connected to the corresponding light-emitting units; and orthographic projections of the first connecting lines on the substrate do not overlap with each other.

In some embodiments, in the second region, an orthographic projection of each driving member on the substrate is located between orthographic projections of the two light-emitting units adjacent to the driving member along the second direction on the substrate.

In some embodiments, in the second region, along an arrangement direction of the m light-emitting units electrically connected to each driving member, m is an even number, and an orthographic projection of each driving member on the substrate is located between orthographic projections of the (m/2)-th light-emitting unit and the (m/2+1)-th light-emitting unit on the substrate; or m is an odd number, and the orthographic projection of each driving member on the substrate is located between orthographic projections of the ((m−1)/2)-th light-emitting unit and the ((m−1)/2+1)-th light-emitting unit on the substrate.

In some embodiments, in the second region, for the c×b light-emitting units at the intersection positions of the c rows of light-emitting units and the b columns of light-emitting units in the first array electrically connected to each driving member, b is an even number, and an orthographic projection of each driving member on the substrate is located between orthographic projections of the (b/2)-th column of light-emitting units and the (b/2+1)-th column of light-emitting units on the substrate, or b is an odd number, and the orthographic projection of each driving member on the substrate is located between orthographic projections of the ((b−1)/2)-th column of light-emitting units and the ((b−1)/2+1)-th column of light-emitting units on the substrate.

In some embodiments, each driving member further includes a body electrically connected to the channels; in the first region, the channels are located on a side of the body close to a corresponding light-emitting unit electrically connected to the driving member, and a corresponding group of second wiring lines is located on a side of the body away from the light-emitting unit electrically connected to the driving member; the first connecting lines extend from the respective channels of the driving member to be electrically connected to the light-emitting units; and orthographic projections of the first connecting lines on the substrate do not overlap with each other.

In some embodiments, in the first region, m is an even number, and an orthographic projection of each driving member on the substrate is located between orthographic projections of the (m/2)-th light-emitting unit and the (m/2+1)-th light-emitting unit electrically connected to the driving member on the substrate; or m is an odd number, and the orthographic projection of each driving member on the substrate is located between orthographic projections of the ((m−1)/2)-th light-emitting unit and the ((m−1)/2+1)-th light-emitting unit electrically connected to the driving member on the substrate.

In some embodiments, in the first region, b is an even number, and an orthographic projection of each driving member on the substrate is located between orthographic projections of the (b/2)-th column of light-emitting units and the (b/2+1)-th column of light-emitting units electrically connected to the driving member on the substrate; or b is an odd number, and the orthographic projection of each driving member on the substrate is located between orthographic projections of the ((b−1)/2)-th column of light-emitting units and the ((b−1)/2+1)-th column of light-emitting units electrically connected to the driving member on the substrate.

In some embodiments, in the first region, a is an even number, and an orthographic projection of each driving member on the substrate is located between orthographic projections of the (a/2)-th row of light-emitting units and the (a/2+1)-th row of light-emitting units electrically connected to the driving member on the substrate; or a is an odd number, and the orthographic projection of each driving member on the substrate is located between orthographic projections of the ((a−1)/2)-th row of light-emitting units and the ((a−1)/2+1)-th row of light-emitting units electrically connected to the driving member on the substrate.

In some embodiments, in the second region, at least one driving member is electrically connected to e light-emitting units sequentially arranged along the first direction and f light-emitting units adjacent to the e light-emitting units along the second direction; and e+f<m, 0<e<m, 0≤f<m, and e and f are integers.

In some embodiments, in the second region, at least one driving member is electrically connected to the c×b light-emitting units at the intersection positions of the c rows of light-emitting units arranged sequentially in the first direction and the b columns of light-emitting units arranged sequentially in the second direction in the first array and g light-emitting units adjacent to the c×b light-emitting units in the second direction; and c×b+g<m, 0≤g<m and g is an integer.

In some embodiments, each group of second wiring lines includes a power signal line, a ground signal line, a data line, a control signal input line, and a control signal output line; the power signal line, the data line, the control signal input line, the ground signal line, and the control signal output line are sequentially arranged along the second direction; each driving member includes m channel output terminals, two power signal terminals, two ground signal terminals, two data signal terminals, a control signal input terminal and a control signal output terminal; the m channel output terminals are electrically connected to m first connecting lines in one-to-one correspondence, respectively; the power signal line is electrically connected to the two power signal terminals of each of a column of driving members; the data line is electrically connected to the two data signal terminals of each of the column of driving members; the ground signal line is electrically connected to the two ground signal terminals of each of the column of driving members; and along the first direction, a control signal input terminal of a first driving member farther from the binding side border region is electrically connected to a control signal output terminal of a second driving member adjacent to the first driving member and closer to the binding side border region, the control signal input terminal of the driving member closest to the binding side border region is electrically connected to the control signal input line, and the control signal output terminal of the driving member farthest from the binding side border region is electrically connected to the control signal output line.

In some embodiments, the m channel output terminals are sequentially arranged at a first end of the body; the two power signal terminals, the two ground signal terminals and the two data signal terminals are symmetrically distributed at a second end and a third end of the body, which are opposite to each other, and the control signal input terminal and the control signal output terminal are located at the second end and the third end of the body, respectively, which are opposite to each other.

In some embodiments, each group of second wiring lines includes a power signal line, b ground signal lines, a data line, a control signal input line, and a control signal output line; the b ground signal lines are located on two opposite sides of a column of driving members electrically connected to the b ground signal lines in the second direction, each ground signal line corresponds to a column of light-emitting units, and an orthographic projection of each ground signal line on the substrate at least partially overlaps with an orthographic projection of the column of light-emitting units on the substrate, and the power signal line, the data line, the control signal input line, and the control signal output line are located between two adjacent ground signal lines.

In some embodiments, each driving member includes m channel output terminals, a power signal terminal, b ground signal terminals, a data signal terminal, a control signal input terminal and a control signal output terminal; the m channel output terminals are electrically connected to m first connecting lines in one-to-one correspondence, respectively; the power signal line is electrically connected to the power signal terminal of each of a column of driving members; the data line is electrically connected to the data signal terminal of each of the column of driving members; the b ground signal lines are electrically connected to the b ground signal terminals of each of the column of driving members in one-to-one correspondence, respectively; and along the first direction, a control signal input terminal of a first driving member farther from the binding side border region is electrically connected to a control signal output terminal of a second driving member adjacent to the first driving member and closer to the binding side border region, the control signal input terminal of the driving member closest to the binding side border region is electrically connected to the control signal input line, and the control signal output terminal of the driving member farthest from the binding side border region is electrically connected to the control signal output line.

In some embodiments, each driving member further includes a body electrically connected to the channels; the m channel output terminals and the power signal terminal are arranged at a first end of the body; the b ground signal terminals, the data signal terminal, the control signal input terminal and the control signal output terminal are arranged at a second end of the body, and the first end and the second end are opposite to each other.

In some embodiments, the light-emitting backplane further includes a layer where the first connecting lines are located and a layer where the plurality of first wiring lines and the plurality of groups of second wiring lines are located; each first connecting line is electrically connected to the corresponding first wiring line through a first via in the insulating layer; the power signal terminals of each column of the driving members are electrically connected to the corresponding power signal line through a second connecting line and a second via in the insulating layer; the data signal terminals of each column of driving members are electrically connected to the corresponding data line through a third connecting line and a third via in the insulating layer; b=2, and one ground signal terminal of each driving member in each column of driving members is electrically connected to one corresponding ground signal line through two fourth connecting lines, one adapter line and a fourth via in the insulating layer; the other ground signal terminal of each driving member in each column of driving members is electrically connected to the other corresponding ground signal line through a fifth connecting line and a fifth via in the insulating layer; along the first direction, a control signal input terminal of a first driving member farther from the binding side border region and a control signal output terminal of a second driving member adjacent to the first driving member and closer to the binding side border region are electrically connected to an intermediate connecting line through a sixth connecting line and a sixth via in the insulating layer, respectively, the control signal input terminal of the driving member closest to the binding side border region is electrically connected to the control signal input line through a seventh connecting line and a seventh via in the insulating layer, and the control signal output terminal of the driving member farthest from the binding side border region is electrically connected to the control signal output line through an eighth connecting line and an eighth via in the insulating layer; the second connecting line, the third connecting line, the fourth connecting line, the fifth connecting line, the sixth connecting line, the seventh connecting line and the eighth connecting line are arranged in the same layer as the first connecting lines, and the adapter line and the intermediate connecting line are arranged in the same layer as the plurality of first wiring lines and the plurality of groups of second wiring lines.

In some embodiments, a line width of each of the ground signal line and the plurality of first wiring lines is greater than that of the power signal line; and the line width of the power signal line is greater than that of each of the data line, the control signal input line, and the control signal output line.

In some embodiments, the power signal line, the ground signal line, the data line, the control signal input line, and the control signal output line extend from the display region to the binding border region, and the plurality of first wiring lines extend from the display region to the binding side border region.

In some embodiments, each light-emitting unit includes at least one light bead, and more than two light beads in each light-emitting unit are connected to each other in series; and a bead at one end of the beads connected to each other in series is close to the corresponding driving member and electrically connected to a corresponding channel of the driving member, and a bead at the other end of the beads connected to each other in series is close to and electrically connected to the corresponding first wiring line.

In some embodiments, the light beads in each light-emitting unit are arranged in any one of a ring shape, a concentric ring shape, a circular shape, an S-shape, a rectangular shape, and a polygonal shape.

In a second aspect, an embodiment of the present disclosure further provides a display apparatus, which includes the above light-emitting backplane.

In some embodiments, the display apparatus further includes a liquid crystal screen, wherein the light-emitting backplane is located on a back side of the liquid crystal screen, and configured to provide backlight for the liquid crystal screen.

### BRIEF DESCRIPTION OF DRAWINGS

The accompanying drawings, which are provided for further understanding of embodiments of the present disclosure and constitute a part of this specification, are for explaining the present disclosure together with the embodiments of the present disclosure, but are not intended to limit the present disclosure. The above and other features and advantages will become more apparent to one of ordinary skill in the art by describing in detail exemplary embodiments thereof with reference to the drawings. In the drawings:

FIG. 1a is a schematic diagram of a wiring design at a far-end sky side away from a binding side border region in a mini-LED single copper layer backplane (a mini-LED backplane having a single layer of copper) in the related art.

FIG. 1b is an enlarged schematic diagram of a portion A in FIG. 1a.

FIG. 1c is a schematic diagram of another wiring design at a far-end sky side away from a binding side border region in a mini-LED single copper layer backplane in the related art.

FIG. 1d is an enlarged schematic diagram of a portion B in FIG. 1c.

FIG. 1e is an enlarged schematic diagram of a portion C in FIG. 1c.

FIG. 2 is a schematic top view of a light-emitting backplane according to an embodiment of the present disclosure.

FIG. 3a is a schematic top view of a light-emitting backplane according to an embodiment of the present disclosure.

FIG. 3b is a schematic cross-sectional diagram of a structure taken along a section line DD′ in FIG. 3a.

FIG. 3c is an enlarged schematic diagram of a portion F in FIG. 3a.

FIG. 3d is an enlarged schematic diagram of a portion G in FIG. 3c.

FIG. 3e is a schematic top view of another light-emitting backplane according to an embodiment of the present disclosure.

FIG. 3f is an enlarged schematic diagram of a portion H in FIG. 3e.

FIG. 3g is an enlarged schematic diagram of a portion I in FIG. 3f.

FIG. 3h is a schematic top view of another light-emitting backplane according to an embodiment of the present disclosure.

FIG. 3i is an enlarged schematic diagram of a portion J in FIG. 3h.

FIG. 3j is a schematic diagram illustrating an example in which some channels of at least one driving member in a second region are idle according to an embodiment of the present disclosure.

FIG. 3k is a schematic top view illustrating an arrangement of wiring lines in a light-emitting backplane according to an embodiment of the present disclosure.

FIG. 3l is a schematic diagram of a distribution of a plurality of ports in a driving member according to an embodiment of the present disclosure.

FIG. 4a is a schematic top view of another light-emitting backplane according to an embodiment of the present disclosure.

FIG. 4b is a schematic cross-sectional diagram of a structure taken along a section line EE′ in FIG. 4a.

FIG. 4c is an enlarged schematic diagram of a portion K in FIG. 4a.

FIG. 4d is an enlarged schematic diagram of a portion M in FIG. 4c.

FIG. 4e is a schematic diagram of another distribution of a plurality of ports in a driving member according to an embodiment of the present disclosure.

FIG. 5 is a schematic cross-sectional diagram of a structure of a display apparatus according to an embodiment of the present disclosure.

### DETAIL DESCRIPTION OF EMBODIMENTS

In order to enable one of ordinary skill in the art to better understand the technical solutions of the embodiments of the present disclosure, a light-emitting backplane and a display apparatus of the embodiments of the present disclosure will be described in further detail with reference to the accompanying drawings and the detailed description.

The embodiments of the present disclosure will be described more fully hereinafter with reference to the accompanying drawings, but the embodiments shown may be embodied in different forms and should not be construed as limited to the embodiments set forth herein. Rather, these embodiments are provided so that this disclosure will be thorough and complete, and will fully convey the scope of the present disclosure to one ordinary skill in the art.

The disclosed embodiments are not limited to the embodiments shown in the drawings, but include modifications of configurations formed based on a manufacturing process. Thus, areas illustrated in the drawings have schematic properties, and shapes of the areas shown in the drawings illustrate specific shapes of the areas of elements, but are not intended to be limiting.

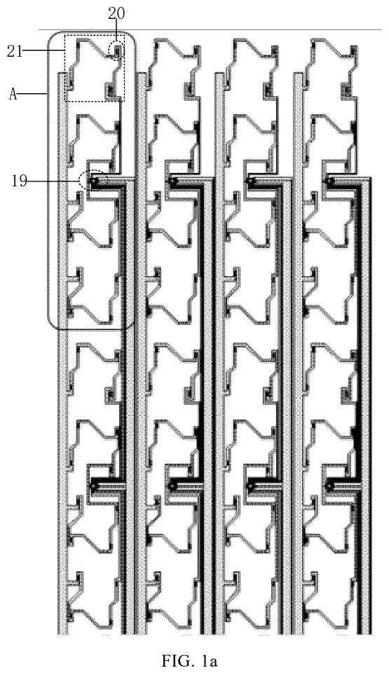

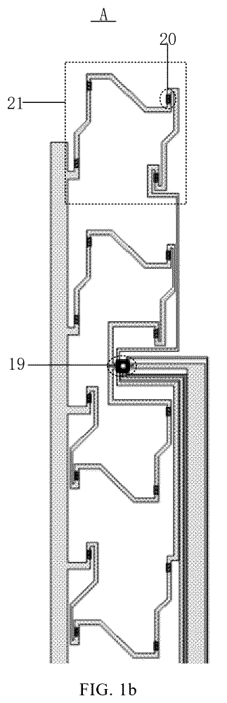

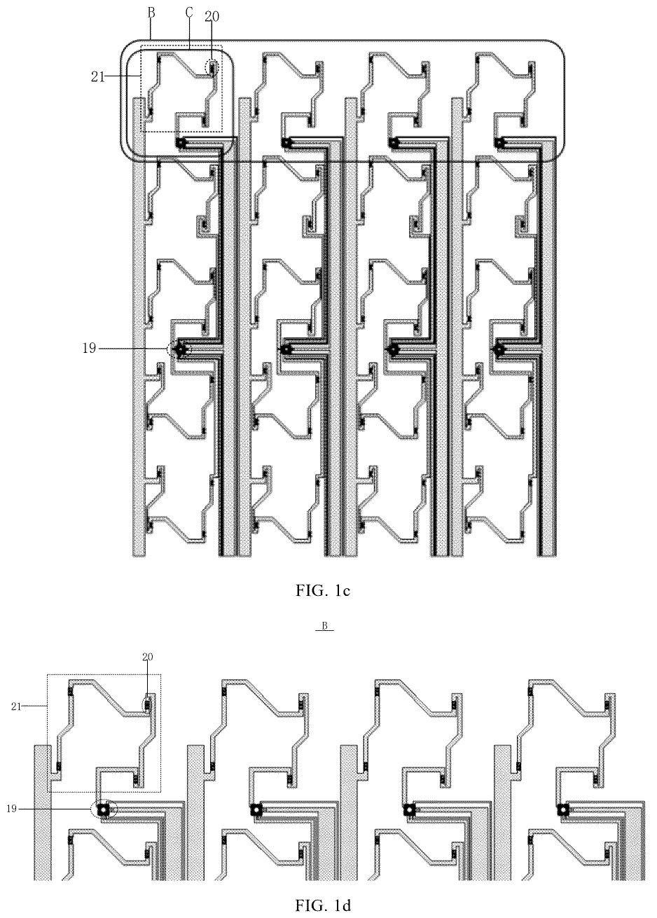

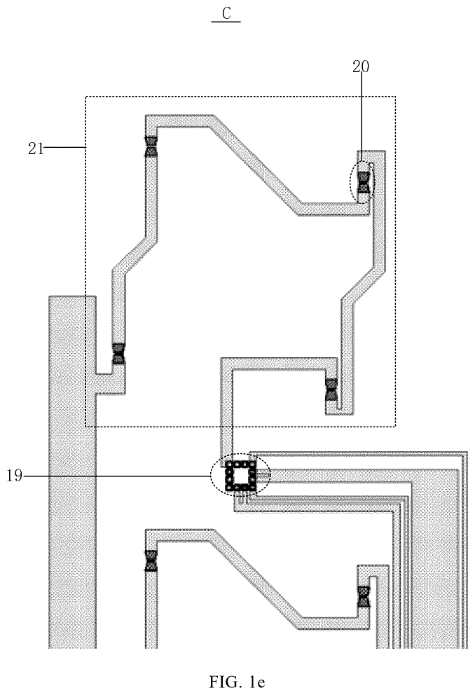

FIG. 1a is a schematic diagram of a wiring design at a far-end sky side away from a binding side border region in a mini-LED single copper layer backplane (a mini-LED backplane having a single layer of copper) in the related art. Referring to FIG. 1a, each driving chip 19 of the mini-LED single copper layer backplane includes four channels (i.e., each driving chip 19 is a 4CH IC), i.e., each driving chip 19 controls four mini-LED light regions 21, each mini-LED light region 21 includes four mini-LED light beads 20 connected in series, and the driving chip 19 is located in the middle of the four mini-LED light regions 21. To achieve the wiring of the mini-LED single copper layer backplane, the four mini-LED light regions 21 controlled by each driving chip 19 are located in the same column.

Signal lines of each column of the mini-LED light regions 21 include a first wiring line, a power signal line, a data line, a control signal input line, a ground signal line, and a control signal output line. Finally, the signal lines extend along a column direction of the mini-LED light regions 21 to a binding side border region, and then are connected to a peripheral circuit board (a printed circuit board assembly, PCBA) through a flexible printed circuit (FPC) board, so that signal input and control of the peripheral circuit board to the signal lines are achieved.

FIG. 1b is an enlarged schematic diagram of a portion A in FIG. 1a. Referring to FIG. 1b, the number of rows of the mini-LED light regions 21 in the mini-LED single copper layer backplane may be evenly divided by four, so that each driving chip 19 controls four mini-LED light regions 21 in the same column in a display region close to the binding side border region of the mini-LED single copper layer backplane, and each driving chip 19 also exactly controls four mini-LED light regions 21 in the same column on a far-end sky side away from the binding side border region of the mini-LED single copper layer backplane. Therefore, four channels of each driving chip 19 are fully utilized.

FIG. 1c is a schematic diagram of another wiring design at a far-end sky side away from a binding side border region in a mini-LED single copper layer backplane in the related art. FIG. 1d is an enlarged schematic diagram of a portion B in FIG. 1c. FIG. le is an enlarged schematic diagram of a portion C in FIG. 1c. However, for some products, when the number of rows of the mini-LED light regions 21 cannot be evenly divided by four, a situation may arise that each driving chip 19 cannot control four mini-LED light regions 21 in the same column on the far-end sky side away from the binding side border region of the mini-LED single copper layer backplane. For example, when the number of rows of the mini-LED light regions 21 is divided by four and the remaining one or two or three rows are left, each driving chip 19 can only control one or two or three mini-LED light regions 21 in the same column on the far-end sky side of the mini-LED single copper layer backplane. In this case, at least one channel of each driving chip 19 on the far-end sky side is in a floating state, so that the driving chip 19 on the far-end sky side cannot be fully utilized. In FIG. 1c, the number of rows of the mini-LED light regions of the mini-LED single copper backplane is divided by four and the remaining one row is left, so that each driving chip 19 controls only one mini-LED light region 21 on the far-end sky side. In this case, three channels of each driving chip 19 are in the floating state, so that driving chips 19 (for example, four driving chips 19 in FIG. 1c) in the whole row on the far-end sky side cannot be fully utilized.

The more the number of the driving chips in the mini-LED single copper layer backplane is, the higher the cost is, and some driving chips cannot be fully utilized, so that the cost is wasted.

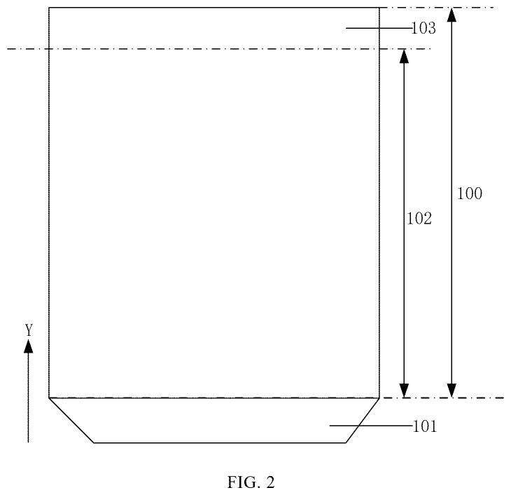

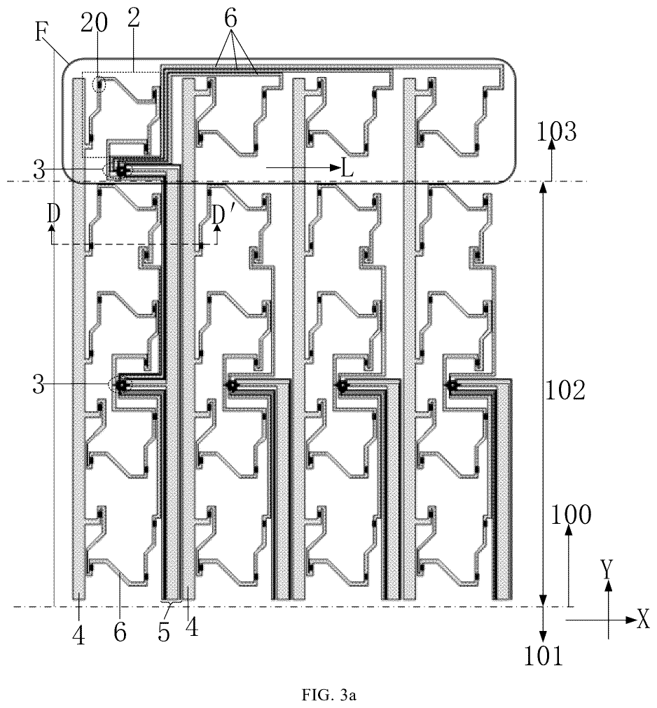

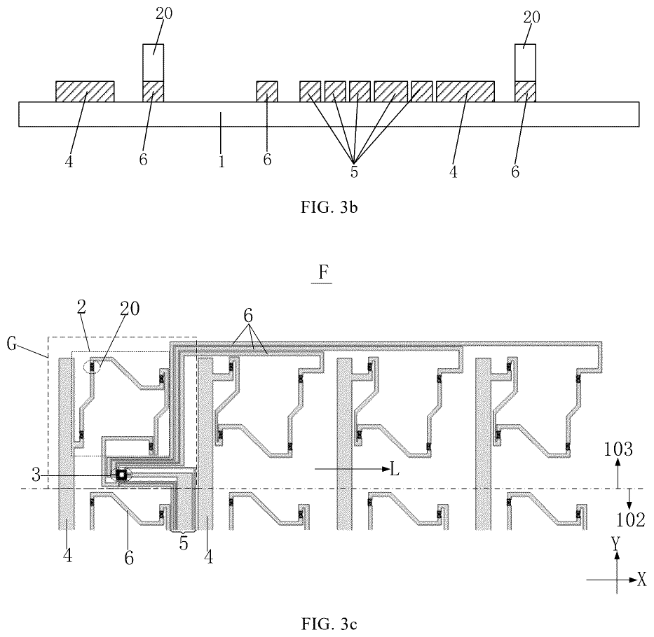

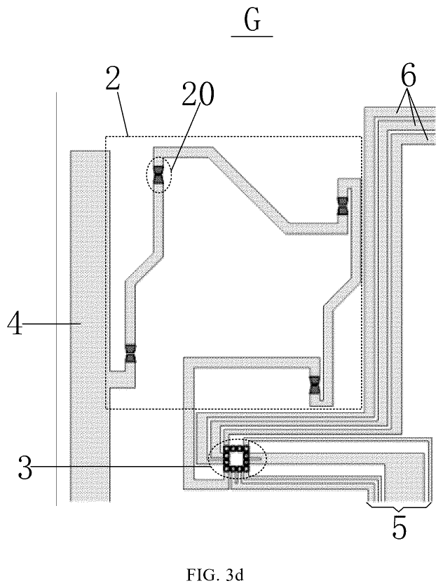

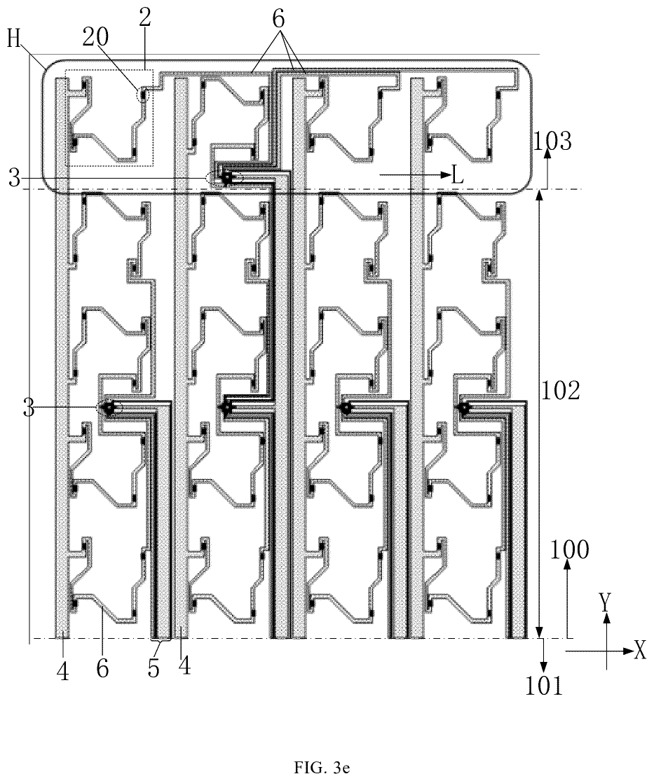

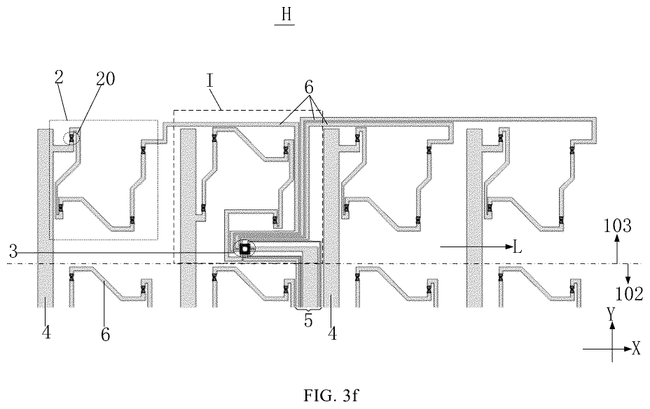

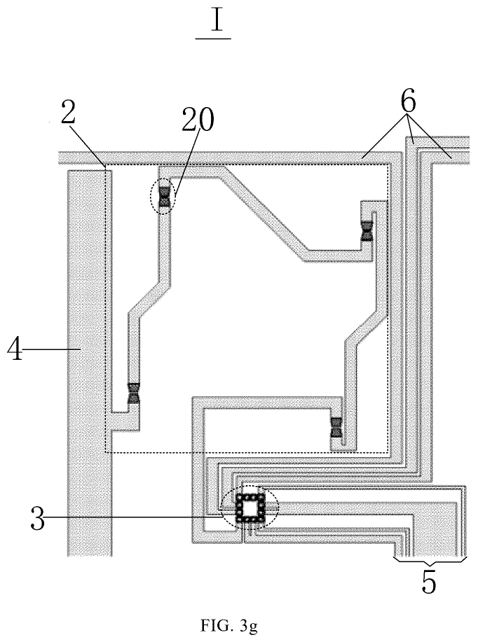

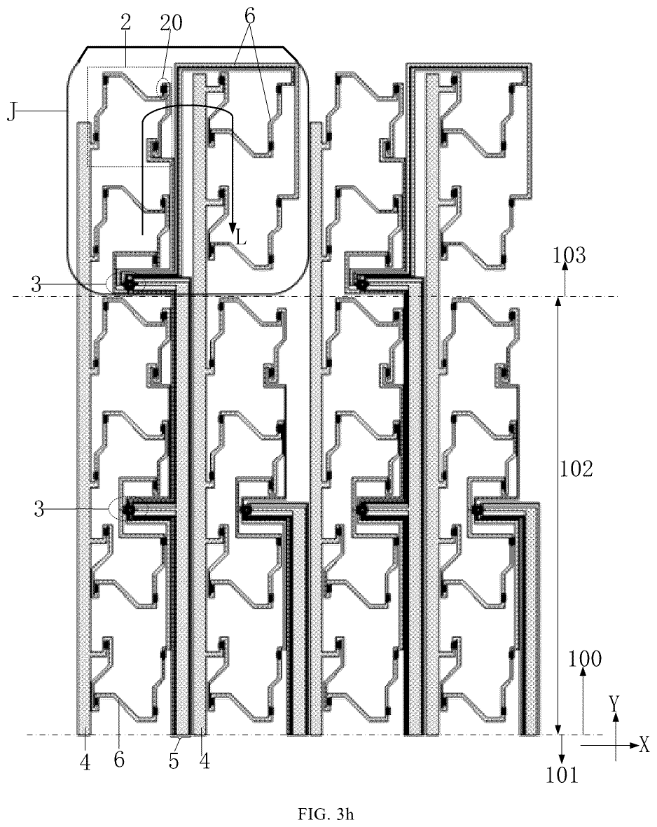

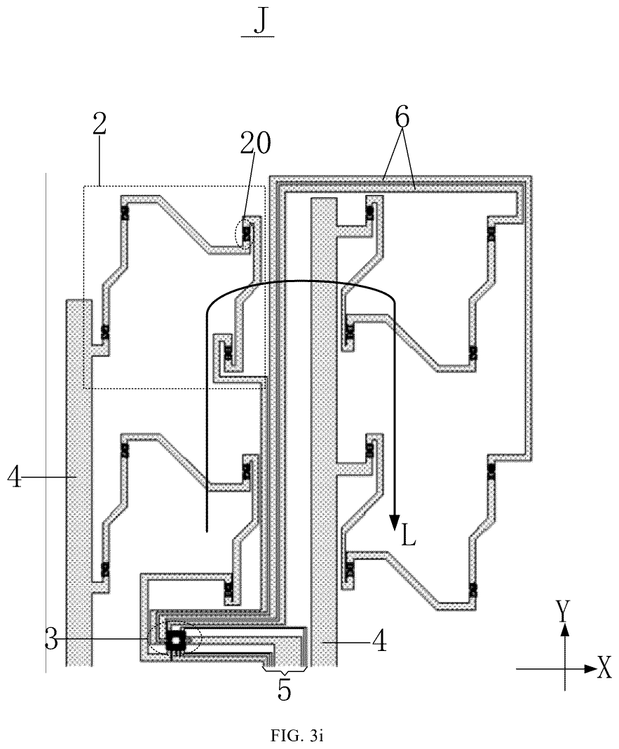

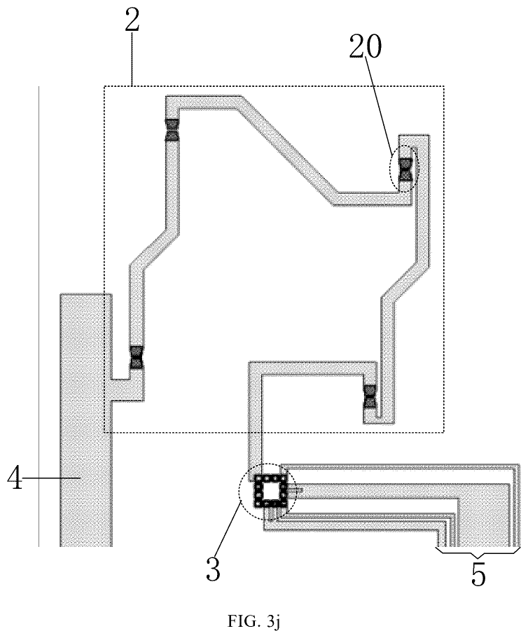

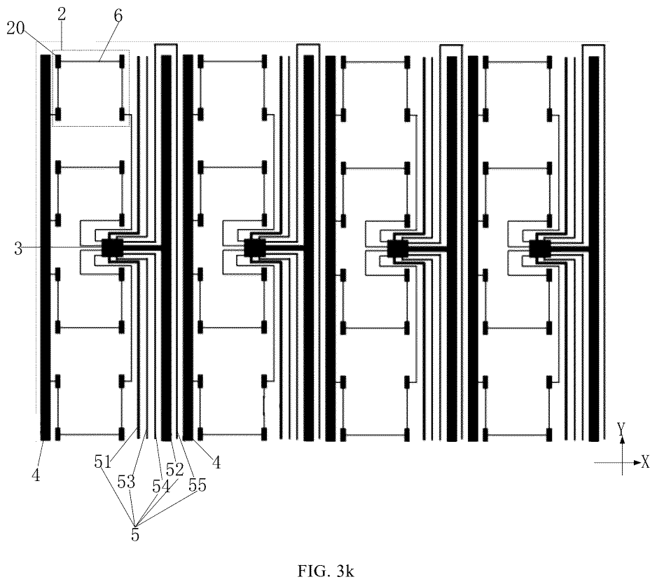

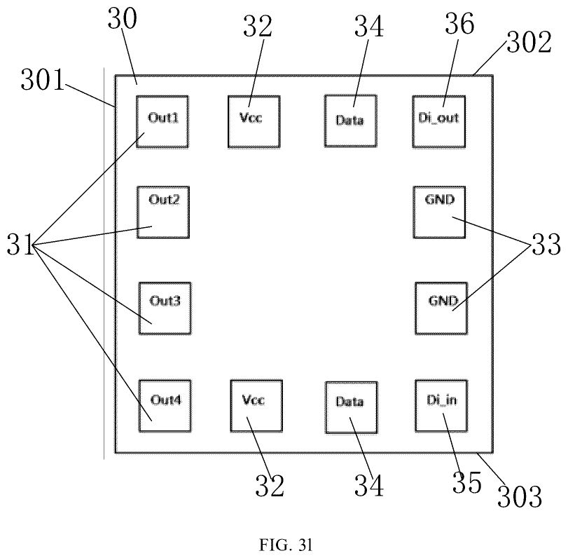

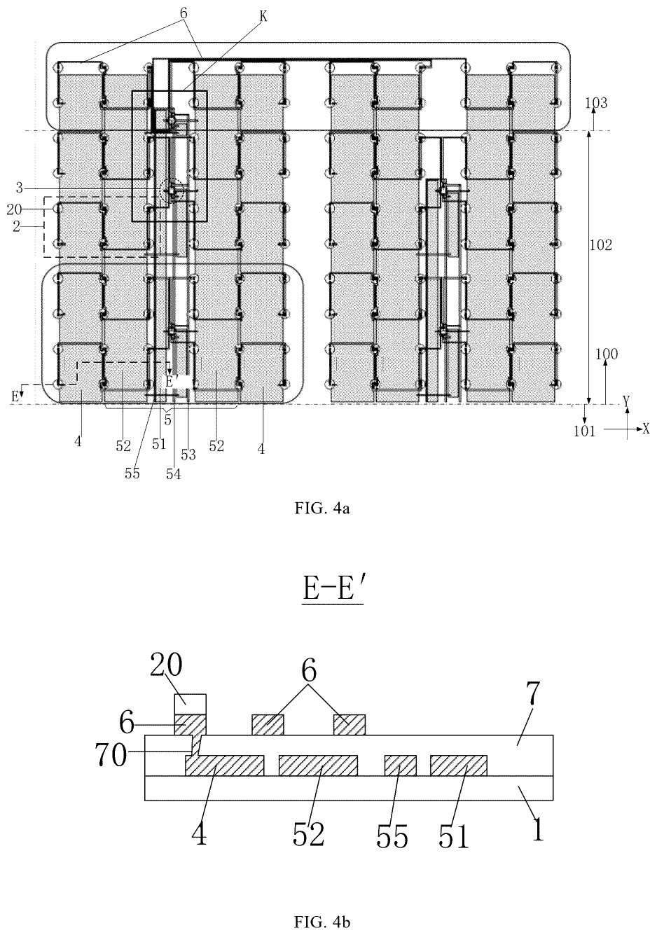

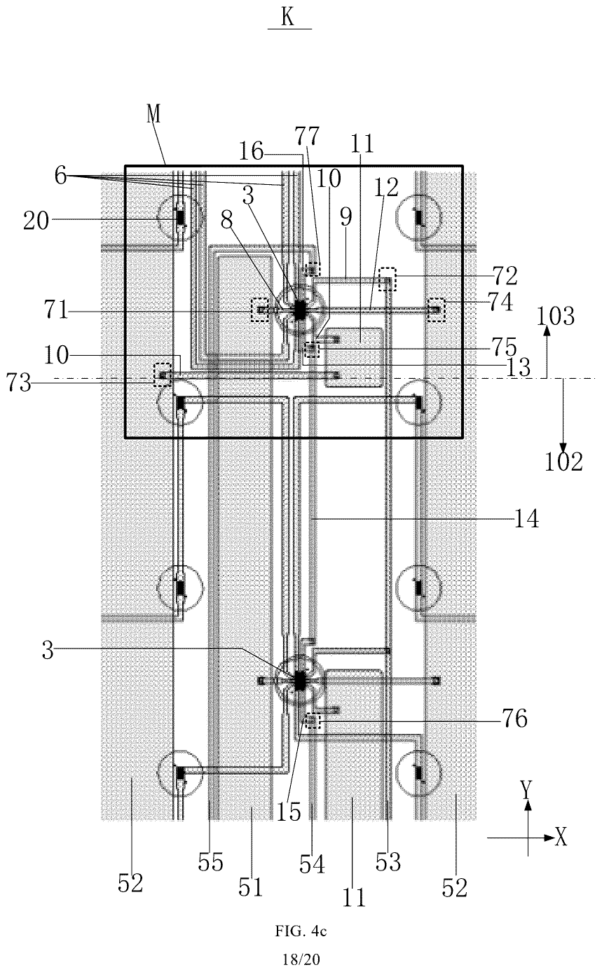

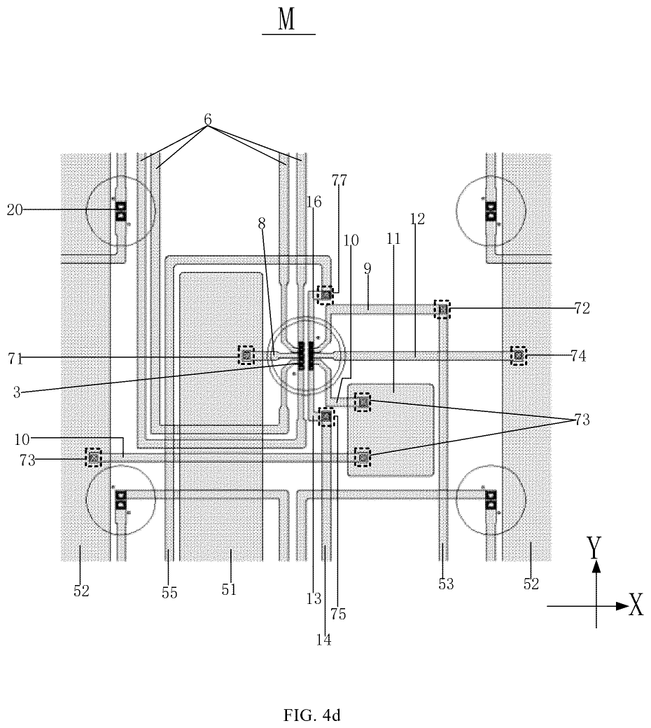

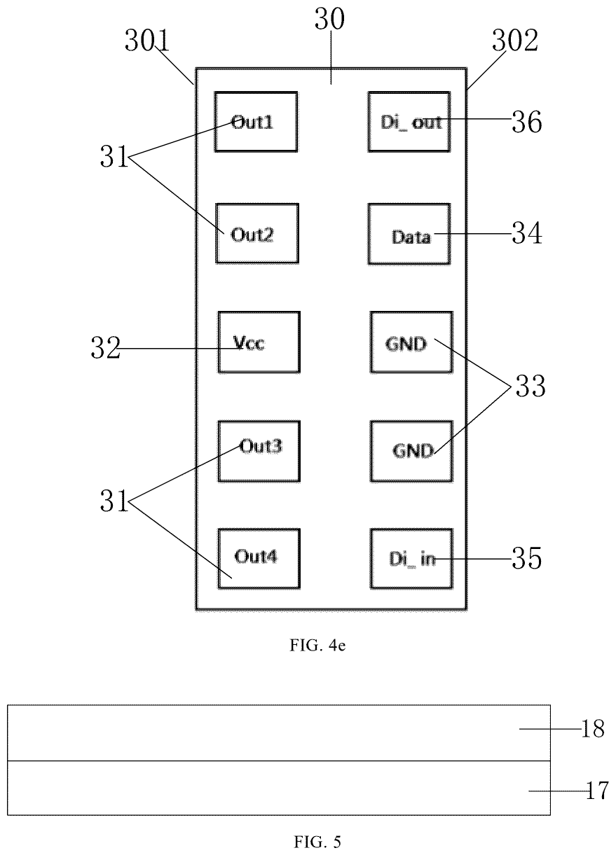

In order to solve the problem that some driving chips cannot be fully utilized in the related art, in a first aspect, an embodiment of the present disclosure provides a light-emitting backplane. FIG. 2 is a schematic top view of a light-emitting backplane according to an embodiment of the present disclosure. FIG. 3a is a schematic top view of a light-emitting backplane according to an embodiment of the present disclosure. FIG. 3b is a schematic cross-sectional diagram of a structure taken along a section line DD′ in FIG. 3a. FIG. 4a is a schematic top view of another light-emitting backplane according to an embodiment of the present disclosure. FIG. 4b is a schematic cross-sectional diagram of a structure taken along a section line EE′ in FIG. 4a. Referring to FIGS. 2, 3a, 3b, 4a and 4b, the light-emitting backplane includes a display region 100 and a binding side border region 101. The binding side border region 101 is located on one side of the display region 100, and the display region 100 includes a first region 102 and a second region 103 sequentially arranged along a first direction Y away from the binding side border region 101. The light-emitting backplane includes: a substrate 1, a plurality of light-emitting units 2, wherein the plurality of light-emitting units 2 are located on one side of the substrate 1, and are arranged in a first array along the first direction Y and a second direction X; and a plurality of driving members 3 located on the side of the substrate 1 where the plurality of light-emitting units 2 are located, wherein the plurality of driving members 3 are arranged in a second array along the first direction Y and the second direction X. The first direction Y and the second direction X intersect with each other. Orthographic projections of the first array and the second array on the substrate 1 do not overlap with each other. Each of the plurality of driving members 3 includes m channels; in the first region 102, each driving member 3 is electrically connected to m light-emitting units 2 at intersection positions of a rows of light-emitting units 2 sequentially arranged along the first direction Y and b columns of light-emitting units 2 sequentially arranged along the second direction X in the first array, and each driving member 3 is electrically connected to different light-emitting units 2; in the second region 103, the total number of rows of light-emitting units 2 in the first array arranged along the first direction Y is c, and each of at least some driving members 3 is electrically connected to c×b light-emitting units 2 at intersection positions of c rows of light-emitting units 2 arranged sequentially along the first direction Y and b columns of light-emitting units 2 arranged sequentially along the second direction X in the first array, and d light-emitting units 2 adjacent to the c×b light-emitting units 2 along the second direction X; 0<c<a, c×b<m, c×b+d=m, a>1, b>0, m>1, 0<d<m, and a, b, c, d, and m are integers.

In some embodiments, referring to FIGS. 3a and 4a, each light-emitting unit 2 includes at least one light bead 20, and more than two light beads 20 in each light-emitting unit 2 are connected to each other in series.

In some embodiments, referring to FIGS. 3a and 4a, the light beads 20 in each light-emitting unit 2 are arranged in any one of a ring shape, a concentric ring shape, a circular shape, an S-shape, a rectangular shape, and a polygonal shape.

In some embodiments, the light beads 20 may be light-emitting elements such as mini-LEDs (mini light-emitting diodes) or LEDs (light-emitting diodes).

In some embodiments, each driving member 3, i.e., the driving chip, is configured to control the brightness change of the light-emitting unit 2. The driving member 3 includes m channels, and each channel may control one light-emitting unit 2 to change the brightness.

In this embodiment, each driving member 3 in the first region 102 is electrically connected to m light-emitting units 2 at intersection positions of a rows of light-emitting units 2 sequentially arranged along the first direction Y and b columns of light-emitting units 2 sequentially arranged along the second direction X in the first array, so that the m channels of each driving member 3 in the first region 102 can be fully utilized. Each of at least some driving members 3 in the second region 103 is electrically connected to c×b light-emitting units 2 at intersection positions of c rows of light-emitting units 2 arranged sequentially along the first direction Y and b columns of light-emitting units 2 arranged sequentially along the second direction X in the first array, and d light-emitting units 2 adjacent to the c×b light-emitting units 2 along the second direction X; where 0<c<a, c×b<m, c×b+d=m, so that each driving member 3 in the second region 103 is electrically connected to the c×b light-emitting units 2 at the intersection positions of the c rows of light-emitting units 2 and the b columns of light-emitting units 2 in the first array, and is then electrically connected to the d light-emitting units 2 adjacent to the c×b light-emitting units 2 along the second direction X through the remaining (m-c×b) channels of the driving member 3, and therefore the m channels of each of at least some driving members 3 in the second region 103 can be fully utilized, the number of the driving members 3 in the second region 103 can be reduced, and the cost of the light-emitting backplane is reduced. Further, the solution of fully utilizing all the channels of each of at least some driving member 3 in the second region 103 only needs to reduce the number of the driving members 3, has little influence on the manufacturing process for the light-emitting backplane, and does not influence reliability of the light-emitting backplane.

In some embodiments, referring to FIG. 3a and FIG. 4a, the light-emitting backplane further includes a plurality of first wiring lines 4 and a plurality of groups of second wiring lines 5, which are located on the side of the substrate 1 where the light-emitting units 2 are located and located on a side of the light-emitting units 2 and the driving members 3 close to the substrate 1, the plurality of first wiring lines 4 and the plurality of groups of second wiring lines 5 are arranged in the same layer, and the plurality of first wiring lines 4 are sequentially arranged along the second direction X, extend along the first direction Y, and are electrically connected to the plurality of columns of the light-emitting units 2 sequentially arranged along the second direction X in the first array in one-to-one correspondence; the plurality of groups of second wiring lines 5 are sequentially arranged along the second direction X, each group of second wiring lines 5 extends along the first direction Y, and the plurality of groups of second wiring lines 5 are electrically connected to the plurality of columns of the driving members 3 sequentially arranged along the second direction X in the second array in one-to-one correspondence.

In some embodiments, the plurality of first wiring lines 4 and the plurality of groups of second wiring lines 5 are routed to the binding side border region 101 along the first direction Y, and are connected to the peripheral circuit board (PCBA) through the flexible printed circuit (FPC) board in the binding side border region 101, so that signal input and control of the peripheral circuit board to the wiring lines are achieved.

In some embodiments, referring to FIGS. 3a and 4a, a bead 20 at one end of the beads 20 connected to each other in series is close to the corresponding driving member 3 and electrically connected to a corresponding channel of the driving member 3, and a bead 20 at the other end of the beads 20 connected to each other in series is close to and electrically connected to the corresponding first wiring line 4.

In some embodiments, the first wiring lines 4 are configured to provide a direct current regulated power supply (e.g., VLED) for the light-emitting units 2 to provide power for lighting the light-emitting units 2, and the direct current regulated power supply provided by the first wiring lines 4 has the same voltage. Each driving member 3 is configured to control the brightness change of the light-emitting units 2 electrically connected to the driving member 3, and each group of second wiring lines 5 is electrically connected to one column of driving members 3 and is configured to provide a power signal and a control signal for controlling the brightness change of the light-emitting units 2 to the connected column of driving members 3. Each driving member 3 is configured to control the on-time of the light-emitting units 2 electrically connected to the driving member 3 in each period (i.e., each frame display). The longer the on-time is, the higher the brightness of the light-emitting units 2 is. The shorter the on-time is, the lower the brightness of the light-emitting units 2 is. In this way, the control of the brightness change of the light-emitting units 2 can be achieved.

In some embodiments, referring to FIG. 3a, a=m, and b=1. That is, in the first region 102, each driving member 3 is electrically connected to the m light-emitting units 2 sequentially arranged along the first direction Y.

In some embodiments, for example, assuming that the first array includes 49 rows×48 columns of light-emitting units 2, and each driving member 3 in the first region 102 is electrically connected to four light-emitting units 2 sequentially arranged along a column direction (i.e., the first direction Y), 49÷4=12 with one remaining row, the remaining one row is located in the second region 103, and every four light-emitting units 2 sequentially arranged along the second direction X in the second region 103 are electrically connected to one driving member 3, and therefore, twelve driving members 3 are required in total. Compared to the solution in the related art in which the remaining one row of light-emitting units 2 include 48 columns in the second region 103 and therefore, 48 driving members 3 are required in total, the number of driving members 3 can be reduced by 36 in this embodiment. For another example, assuming that the first array includes 50 rows×48 columns of light-emitting units 2, and each driving member 3 in the first region 102 is electrically connected to four light-emitting units 2 sequentially arranged along the column direction (i.e., the first direction Y), 50÷4=12 with two remaining rows, the remaining two rows are located in the second region 103, and every two light-emitting units 2 sequentially arranged along the first direction Y and two light-emitting units 2 in a second column adjacent to these two light-emitting units 2 along the second direction X in the second region 103 are electrically connected to one driving member 3, and therefore, 24 driving members 3 are required in total. Compared to the solution in the related art in which the remaining two rows of light-emitting units 2 include 48 columns in the second region 103 and therefore, 48 driving members 3 are required in total, the number of driving members 3 can be reduced by 24 in this embodiment. For another example, assuming that the first array includes 51 rows×48 columns of light-emitting units 2, and each driving member 3 in the first region 102 is electrically connected to four light-emitting units 2 sequentially arranged along the column direction (i.e., the first direction Y), 51÷4=12 with three remaining rows, the remaining three rows are located in the second region 103, and every three light-emitting units 2 sequentially arranged along the first direction Y and one light-emitting unit 2 in a second column adjacent to these three light-emitting units 2 along the second direction X in the second region 103 are electrically connected to one driving member 3, and therefore, 36 driving members 3 are required in total. Compared to the solution in the related art in which the remaining three rows of light-emitting units 2 include 48 columns in the second region 103 and therefore, 48 driving members 3 are required in total, the number of driving members 3 can be reduced by 12 in this embodiment.

In some embodiments, referring to FIG. 3b, a first wiring line 4 electrically connected to the light-emitting units 2 in the same column and a group of second wiring lines 5 electrically connected to the driving members 3 in a column are respectively located on two opposite sides of the column of light-emitting units 2 along the second direction X. An orthographic projection of each driving member 3 on the substrate 1 is located between orthographic projections of the two light-emitting units 2 adjacent to the driving member 3 along the first direction Y on the substrate 1. The m channels are electrically connected to different light-emitting units 2 through different first connecting lines 6, respectively, the first connecting lines 6, the first wiring lines 4 and the second wiring lines 5 are arranged in the same layer, and orthographic projections of the first connecting lines 6, the first wiring lines 4 and the second wiring lines 5 on the substrate 1 do not overlap with each other. With the arrangement, the first wiring lines 4, the second wiring lines 5 and the first connecting lines 6 are distributed in the single conductive layer, that is, the wiring of the single conductive layer of the light-emitting backplane is realized.

In some embodiments, the first wiring lines 4 and the second wiring lines 5 are arranged alternately in sequence along the second direction X.

FIG. 3c is an enlarged schematic diagram of a portion F in FIG. 3a. FIG. 3d is an enlarged schematic diagram of a portion G in FIG. 3c. FIG. 3e is a schematic top view of another light-emitting backplane according to an embodiment of the present disclosure. FIG. 3f is an enlarged schematic diagram of a portion H in FIG. 3e. FIG. 3g is an enlarged schematic diagram of a portion I in FIG. 3f. FIG. 3h is a schematic top view of another light-emitting backplane according to an embodiment of the present disclosure. FIG. 3i is an enlarged schematic diagram of a portion J in FIG. 3h. In some embodiments, referring to FIGS. 3a, 4a, 3c, 3d, 3e, 3f, 3g, 3h and 3i, in the second region 103, the first connecting lines 6 extend from the respective channels of the driving member 3 to one side of the second region 103 away from the first region 102 and are electrically connected to the corresponding light-emitting units 2. Orthographic projections of the first connecting lines 6 on the substrate 1 do not overlap with each other. With such the arrangement, with reference to FIGS. 3a to 3i, when each driving member 3 is electrically connected to (m−c) light-emitting units 2 adjacent to the c light-emitting units 2 along the second direction X, the m first connecting lines 6 do not intersect with each other, and have sufficient wiring space to be electrically connected to the light-emitting units 2. Similarly, with such the arrangement, referring to FIG. 4a, when each driving member 3 is electrically connected to (m−c×b) light-emitting units 2 adjacent to the c×b light-emitting units 2 along the second direction X, the m first connecting lines 6 do not intersect with each other, and have sufficient wiring space to be electrically connected to the light-emitting units 2.

In some embodiments, referring to FIGS. 3a, 3e, 3h and 4a, in the second region 103, an orthographic projection of each driving member 3 on the substrate 1 is located between orthographic projections of the two light-emitting units 2 adjacent to the driving member 3 along the second direction X on the substrate 1.

In some embodiments, referring to FIGS. 3a and 4a, in the second region 103, the orthographic projection of each driving member 3 on the substrate 1 is located between orthographic projections of a first light-emitting unit 2 and a second light-emitting unit 2 adjacent to the driving member 3 along the second direction X on the substrate 1. Referring to FIG. 3e, in the second region 103, the orthographic projection of each driving member 3 on the substrate 1 is located between orthographic projections of the second light-emitting unit 2 and a third light-emitting unit 2 adjacent to the driving member 3 along the second direction X on the substrate 1. In some embodiments, referring to FIGS. 3a and 3e, in the second region 103, the orthographic projection of each driving member 3 on the substrate 1 is located between orthographic projections of the third light-emitting unit 2 and a fourth light-emitting unit 2 adjacent to the driving member 3 along the second direction X on the substrate 1. Referring to FIG. 3h, in the second region 103, the orthographic projection of each driving member 3 on the substrate 1 is located between the orthographic projections of the first light-emitting unit 2 and the fourth light-emitting unit 2 adjacent to the driving member 3 along the second direction X on the substrate 1.

In some embodiments, referring to FIG. 3e, in the second region 103, along an arrangement direction L of the m light-emitting units 2 electrically connected to each driving member 3, when m is an even number, the orthographic projection of each driving member 3 on the substrate 1 is located between orthographic projections of the (m/2)-th light-emitting unit 2 and the (m/2+1)-th light-emitting unit 2 on the substrate 1. When m is an odd number, the orthographic projection of each driving member 3 on the substrate 1 is located between orthographic projections of the ((m−1)/2)-th light-emitting unit 2 and the ((m−1)/2+1)-th light-emitting unit 2 on the substrate 1.

Referring to FIGS. 3e and 3a, the arrangement direction L of the m light-emitting units 2 electrically connected to each driving member 3 may be a linear direction. Referring to FIG. 3h, the arrangement direction L of the m light-emitting units 2 electrically connected to each driving member 3 may alternatively be a curved direction. The driving member 3 is arranged in the middle in the arrangement direction L of the even number of the light-emitting units 2 electrically connected to the driving member 3, or at a position close to the middle in the arrangement direction L of the odd number of the light-emitting units 2 electrically connected to the driving member 3, so that an extending length of each of at least part of the m first connecting lines 6 can be shortened, the loss of signals on the first connecting lines 6 is reduced, and the display quality of the light-emitting backplane is improved. Meanwhile, the wiring cost of the first connecting lines 6 can be reduced, and therefore, the manufacturing cost and the process cost of the light-emitting backplane are reduced.

In some embodiments, referring to FIGS. 3d, 3g and 3i, the driving member 3 further includes a body 30 electrically connected to the channels. In the first region 102, the channels are located on a side of the body 30 close to a corresponding light-emitting unit 2 electrically connected to the driving member 3, and a corresponding group of second wiring lines 5 is located on a side of the body 30 away from the light-emitting unit 2 electrically connected to the driving member 3. The first connecting lines 6 extend from the respective channels of the driving member 3 to be electrically connected to the light-emitting units 2. The orthographic projections of the first connecting lines 6 on the substrate 1 do not overlap with each other.

In some embodiments, referring to FIGS. 3a, 3e and 3h, in the first region 102, when m is an even number, the orthographic projection of each driving member 3 on the substrate 1 is located between orthographic projections of the (m/2)-th light-emitting unit 2 and the (m/2+1)-th light-emitting unit 2 electrically connected to the driving member 3 on the substrate 1. When m is an odd number, the orthographic projection of each driving member 3 on the substrate 1 is located between orthographic projections of the ((m−1)/2)-th light-emitting unit 2 and the ((m−1)/2+1)-th light-emitting unit 2 electrically connected to the driving member 3 on the substrate 1.

Referring to FIGS. 3a, 3e, and 3h, in the first region 102, the m light-emitting units 2 electrically connected to the same driving member 3 are sequentially arranged along the first direction Y. The driving member 3 is arranged in the middle in the first direction Y of the even number of the light-emitting units 2 electrically connected to the driving member 3, or at a position close to the middle in the first direction Y of the odd number of the light-emitting units 2 electrically connected to the driving member 3, so that an extending length of each of at least part of the m first connecting lines 6 can be further shortened, the loss of signals on the first connecting lines 6 is further reduced, and the display quality of the light-emitting backplane is improved. Meanwhile, the wiring cost of the first connecting lines 6 can be further reduced, and therefore, the manufacturing cost and the process cost of the light-emitting backplane are further reduced.

FIG. 3j is a schematic diagram illustrating that respective channels of at least one driving member in a second region are idle according to an embodiment of the present disclosure. In some embodiments, referring to FIG. 3j, in the second region 103, at least one driving member 3 is electrically connected to e light-emitting units 2 sequentially arranged along the first direction Y and f light-emitting units 2 adjacent to the e light-emitting units 2 along the second direction X, e+f<m, 0<e<m, 0≤f<m, and e and f are integers. That is, due to the limitation of the number of light-emitting units 2 in the first array, the channels of the last driving member 3 in the second region 103 may not be fully utilized, for example, respective channels are idle.

FIG. 3k is a schematic top view illustrating an arrangement of wiring lines in a light-emitting backplane according to an embodiment of the present disclosure. FIG. 31 is a schematic diagram of a distribution of a plurality of ports in a driving member according to an embodiment of the present disclosure. In some embodiments, referring to FIG. 3k and FIG. 3l, each group of second wiring lines 5 includes a power signal line 51, a ground signal line 52, a data line 53, a control signal input line 54, and a control signal output line 55, the power signal line 51, the data line 53, the control signal input line 54, the ground signal line 52, and the control signal output line 55 are sequentially arranged along the second direction X, each driving member 3 includes m channel output terminals 31, two power signal terminals 32, two ground signal terminals 33, two data signal terminals 34, a control signal input terminal 35 and a control signal output terminal 36, the m channel output terminals are electrically connected to m first connecting lines 6 in one-to-one correspondence, respectively, the power signal line 51 is electrically connected to the two power signal terminals 32 of each of a column of driving members 3, the data line 53 is electrically connected to the two data signal terminals 34 of each of the column of driving members 3, and the ground signal line 52 is electrically connected to the two ground signal terminals 33 of each of the column of driving members 3; along the first direction Y, a control signal input terminal 35 of a first driving member 3 farther from the binding side border region 101 is electrically connected to a control signal output terminal 36 of a second driving member 3 adjacent to the first driving member 3 and closer to the binding side border region 101, the control signal input terminal 35 of the driving member 3 closest to the binding side border region 101 is electrically connected to the control signal input line 54, and the control signal output terminal 36 of the driving member 3 farthest from the binding side border region 101 is electrically connected to the control signal output line 55.

Referring to FIG. 3k, the signal lines in each group of second wiring lines 5 do not intersect with each other, and each group of second wiring lines 5, the first wiring lines 4 and the first connecting lines 6 also do not intersect with each other, so that the second wiring lines 5, the first wiring lines 4 and the first connecting lines 6 may be formed in the same conductive layer. That is, a wiring scheme for a single conductive layer of the light-emitting backplane can be realized.

In some embodiments, referring to FIG. 31, the m channel output terminals 31 are sequentially arranged at a first end 301 of the body 30, the two power signal terminals 32, the two ground signal terminals 33 and the two data signal terminals 34 are symmetrically distributed at a second end 302 and a third end 303 of the body 30, which are opposite to each other, and the control signal input terminal 35 and the control signal output terminal 36 are located at the second end 302 and the third end 303 of the body 30, respectively, which are opposite to each other. In this way, each driving member 3 is conveniently connected to the signal lines in each group of second wiring lines 5 and the first connecting lines 6 while the signal lines in each group of second wiring lines 5 and the first connecting lines 6 are prevented from crossing with each other.

In some embodiments, referring to FIGS. 3a, 3e, 3h, 3k and 4a, a line width of each of the ground signal line 52 and the first wiring lines 4 is greater than that of the power signal line 51, which is in turn greater than that of each of the data line 53, the control signal input line 54, and the control signal output line 55. With this arrangement, it is convenient to reduce wiring resistances of the ground signal line 52 and the first wiring lines 4 and the power signal line 51, thereby reducing the loss of signals on the first wiring lines 4 and the power signal line 51 while a ground signal can be quickly grounded (transmitted to the ground) through the ground signal line 52.

In some embodiments, the power signal line 51, the ground signal line 52, the data line 53, the control signal input line 54, and the control signal output line 55 extend from the display region 100 to the binding border region 101, and the first wiring lines 4 extend from the display region 100 to the binding side border region 101. In the binding side border region 101, the signal lines and the first wiring lines 4 are connected to the peripheral circuit board (PCBA) through the flexible printed circuit (FPC), so that signal input and control of the peripheral circuit board to the signal lines and the first wiring lines 4 are realized.

In some embodiments, referring to FIG. 4a, a>1, and b>1. That is, in the first region 102, each driving member 3 is electrically connected to at least four light-emitting units 2 at intersection positions of two rows of light-emitting units 2 and two columns of light-emitting units 2 in the first array.

In some embodiments, for example, assuming that the first array includes 49 rows×48 columns of light-emitting units 2, and each driving member 3 in the first region 102 is electrically connected to four light-emitting units 2 at intersection positions of two rows of light-emitting units 2 and two columns of light-emitting units 2 in the first array, 49÷2=24 with one remaining row, the remaining one row is located in the second region 103, every two light-emitting units 2 at intersection positions of the remaining one row and two columns in the first array and two light-emitting units 2 adjacent to these two light-emitting units 2 along the second direction X in the second region 103 are electrically connected to one driving member 3, and therefore, twelve driving members 3 are required in total. Compared to the solution in the related art in which the remaining one row of light-emitting units 2 include 48 columns in the second region 103, every two columns of light-emitting units 2 are electrically connected to one driving member 3 and therefore, 24 driving members 3 are required in total, the number of driving members 3 can be reduced by 12 in this embodiment.

In some embodiments, referring to FIG. 4a, any one column of the columns of the driving members 3 sequentially arranged along the second direction X is located between two columns of light-emitting units 2 sequentially arranged along the second direction X adjacent to the column of the driving members 3, the m channels are electrically connected to different light-emitting units 2 through different first connecting lines 6, respectively, the first connecting lines 6 are located on a side of the first wiring lines 4 and the second wiring lines 5 away from the substrate 1, and on a side of the light-emitting units 2 and the driving members 3 close to the substrate 1, and orthographic projections of the first connecting lines 6, the first wiring lines 4 and the second wiring lines 5 on the substrate 1 at least partially overlap with each other. In this way, the first wiring lines 4 and the second wiring lines 5 are distributed in a layer different from a layer where the first connecting lines 6 are located. That is, a wiring in two conductive layers of the light-emitting backplane can be realized.

In some embodiments, referring to FIG. 4a, along the second direction X, any one group of second wiring lines 5 is located between two first wiring lines 4 adjacent to the group of second wiring lines 5, and orthographic projections of the first wiring line 4 and the corresponding column of light-emitting units 2 electrically connected to the first wiring line 4 on the substrate 1 at least partially overlap with each other.

In some embodiments, referring to FIG. 4a, in the second region 103, for the c×b light-emitting units 2 at the intersection positions of the c rows of light-emitting units 2 and the b columns of light-emitting units 2 in the first array electrically connected to each driving member 3, when b is an even number, an orthographic projection of the driving member 3 on the substrate 1 is located between orthographic projections of the (b/2)-th column of light-emitting units 2 and the (b/2+1)-th column of light-emitting units 2 on the substrate 1, and when b is an odd number, the orthographic projection of the driving member 3 on the substrate 1 is located between orthographic projections of the ((b−1)/2)-th column of light-emitting units 2 and the ((b−1)/2+1)-th column of light-emitting units 2 on the substrate 1.

Referring to FIG. 4a, in the second region 103, each driving member 3 is arranged in the middle or at a position close to the middle in the b columns of the light-emitting units 2 electrically connected to the driving member 3, so that an extending length of each of at least part of the m first connecting lines 6 can be shortened, the loss of signals on the first connecting lines 6 is reduced, and the display quality of the light-emitting backplane is improved. Meanwhile, the wiring cost of the first connecting lines 6 can be reduced, and therefore, the manufacturing cost and the process cost of the light-emitting backplane are reduced.

In some embodiments, referring to FIG. 4a, in the first region 102, whenb is an even number, an orthographic projection of each driving member 3 on the substrate 1 is located between orthographic projections of the (b/2)-th column of light-emitting units 2 and the (b/2+1)-th column of light-emitting units 2 electrically connected to the driving member 3 on the substrate 1, and when b is an odd number, the orthographic projection of each driving member 3 on the substrate 1 is located between orthographic projections of the ((b−1)/2)-th column of light-emitting units 2 and the ((b−1)/2+1)-th column of light-emitting units 2 electrically connected to the driving member 3 on the substrate 1.

In some embodiments, referring to FIG. 4a, in the first region 102, when a is an even number, the orthographic projection of each driving member 3 on the substrate 1 is located between orthographic projections of the (a/2)-th row of light-emitting units 2 and the (a/2+1)-th row of light-emitting units 2 electrically connected to the driving member 3 on the substrate 1, and when a is an odd number, the orthographic projection of each driving member 3 on the substrate 1 is located between orthographic projections of the ((a−1)/2)-th row of light-emitting units 2 and the ((a−1)/2+1)-th row of light-emitting units 2 electrically connected to the driving member 3 on the substrate 1.

Referring to FIG. 4a, in the first region 102, each driving member 3 electrically connected to the m light-emitting units 2 is arranged in the middle or at a position close to the middle in the orthographic projections of the a rows of light-emitting units 2 and the b columns of light-emitting units 2 in the first array on the substrate 1, so that an extending length of each of at least part of the m first connecting lines 6 can be further shortened, the loss of signals on the first connecting lines 6 is further reduced, and the display quality of the light-emitting backplane is improved. Meanwhile, the wiring cost of the first connecting lines 6 can be further reduced, and therefore, the manufacturing cost and the process cost of the light-emitting backplane are reduced.

In some embodiments, in the second region 103, the at least one driving member 3 is electrically connected to the c×b light-emitting units 2 at the intersection positions of the c rows of light-emitting units 2 arranged sequentially in the first direction Y and the b columns of light-emitting units 2 arranged sequentially in the second direction X in the first array and g light-emitting units 2 adjacent to the c×b light-emitting units 2 in the second direction X, where c×b+g<m, 0≤g<m, and g is an integer. That is, due to the limitation of the number of light-emitting units 2 in the first array, the channels of the last driving member 3 in the second region 103 may not be fully utilized, for example, respective channels are idle.

FIG. 4c is an enlarged schematic diagram of a portion K in FIG. 4a. FIG. 4d is an enlarged schematic diagram of a portion M in FIG. 4c. In some embodiments, referring to FIGS. 4a, 4c and 4d, each group of second wiring lines 5 includes a power signal line 51, b ground signal lines 52, a data line 53, a control signal input line 54, and a control signal output line 55, the b ground signal lines 52 are located on two opposite sides of a column of driving members 3 electrically connected to the ground signal lines in the second direction X, each ground signal line 52 corresponds to a column of light-emitting units 2, an orthographic projection of each ground signal line 52 on the substrate 1 at least partially overlaps with an orthographic projection of the column of light-emitting units 2 on the substrate 1, and the power signal line 51, the data line 53, the control signal input line 54, and the control signal output line 55 are located between two adjacent ground signal lines 52.

In some embodiments, referring to FIG. 4a, b=2, each group of second wiring lines 5 includes two ground signal lines 52.

FIG. 4e is a schematic diagram of another distribution of a plurality of ports in a driving member according to an embodiment of the present disclosure. In some embodiments, referring to FIGS. 4a and 4e, each driving member 3 includes m channel output terminals 31, a power signal terminal 32, b ground signal terminals 33, a data signal terminal 34, a control signal input terminal 35 and a control signal output terminal 36, the m channel output terminals are electrically connected to m first connecting lines 6 in one-to-one correspondence, respectively, the power signal line 51 is electrically connected to the power signal terminal 32 of each of a column of driving members 3, the data line 53 is electrically connected to the data signal terminal 34 of each of the column of driving members 3, and the b ground signal lines 52 are electrically connected to the b ground signal terminals 33 of each of the column of driving members 3 in one-to-one correspondence, respectively; along the first direction Y, a control signal input terminal 35 of a first driving member 3 farther from the binding side border region 101 is electrically connected to a control signal output terminal 36 of a second driving member 3 adjacent to the first driving member 3 and closer to the binding side border region 101, the control signal input terminal 35 of the driving member 3 closest to the binding side border region 101 is electrically connected to the control signal input line 54, and the control signal output terminal 36 of the driving member 3 farthest from the binding side border region 101 is electrically connected to the control signal output line 55.

In some embodiments, referring to FIG. 4e, each driving member 3 includes two ground signal terminals 33.

In some embodiments, referring to FIG. 4e, each driving member 3 further includes a body 30 electrically connected to the m channels. The m channel output terminals 31 and the power signal terminal 32 are arranged at a first end 301 of the body 30, the b ground signal terminals 33, the data signal terminal 34, the control signal input terminal 35 and the control signal output terminal 36 are arranged at a second end 302 of the body 30, and the first end 301 and the second end 302 are opposite to each other. In this way, each driving member 3 is conveniently connected to the signal lines in each group of second wiring lines 5 and the first connecting lines 6.

In some embodiments, referring to FIGS. 4a, 4b, 4c and 4d, an insulating layer 7 is disposed between a layer where the first connecting lines 6 are located and a layer where the first wiring lines 4 and the second wiring lines 5 are located, each first connecting line 6 is electrically connected to the corresponding first wiring line 4 through a first via 70 in the insulating layer 7, the power signal terminals 32 of each column of the driving members 3 are electrically connected to the corresponding power signal line 51 through a second connecting line 8 and a second via 71 in the insulating layer 7, the data signal terminals 34 of each column of driving members 3 are electrically connected to the corresponding data line 53 through a third connecting line 9 and a third via 72 in the insulating layer 7, where b=2, one ground signal terminal 33 of each driving member 3 in each column of driving members 3 is electrically connected to one corresponding ground signal line 52 through two fourth connecting lines 10, one adapter line 11 and a fourth via 73 in the insulating layer 7, and the other ground signal terminal 33 of each driving member 3 in each column of driving members 3 is electrically connected to the other corresponding ground signal line 52 through a fifth connecting line 12 and a fifth via 74 in the insulating layer 7; along the first direction Y, a control signal input terminal 35 of a first driving member 3 farther from the binding side border region 101 and a control signal output terminal 36 of a second driving member 3 adjacent to the first driving member 3 and closer to the binding side border region 101 are electrically connected to an intermediate connecting line 14 through a sixth connecting line 13 and a sixth via 75 in the insulating layer 7, respectively, the control signal input terminal 35 of the driving member 3 closest to the binding side border region 101 is electrically connected to the control signal input line 54 through a seventh connecting line 15 and a seventh via 76 in the insulating layer 7 and the control signal output terminal 36 of the driving member 3 farthest from the binding side border region 101 is electrically connected to the control signal output line 55 through an eighth connecting line 16 and an eighth via 77 in the insulating layer 7. The second connecting line 8, the third connecting line 9, the fourth connecting line 10, the fifth connecting line 12, the sixth connecting line 13, the seventh connecting line 15 and the eighth connecting line 16 are arranged in the same layer as the first connecting lines 6, and the adapter line 11 and the intermediate connecting line 14 are disposed in the same layer as the first wiring lines 4 and the second wiring lines 5.

Referring to FIGS. 4a, 4b, 4c, and 4d, each signal line in each group of second wiring lines 5 and the first wiring lines 4 are located in the same conductive layer, and may be formed by forming one conductive layer at the same time. The first connecting lines 6, the second connecting line 8, the third connecting line 9, the fourth connecting line 10, the fifth connecting line 12, the sixth connecting line 13, the seventh connecting line 15 and the eighth connecting line 16 are located in another conductive layer and may be formed by forming another conductive layer at the same time. In this way, a wiring scheme for two conductive layers of the light-emitting backplane can be realized.

According to the light-emitting backplane provided by the embodiment of the present disclosure, each driving member 3 in the first region 102 is electrically connected to m light-emitting units 2 at intersection positions of a rows of light-emitting units 2 sequentially arranged along the first direction Y and b columns of light-emitting units 2 sequentially arranged along the second direction X in the first array, so that the m channels of each driving member 3 in the first region 102 can be fully utilized. Each of at least some driving members 3 in the second region 103 is electrically connected to c×b light-emitting units 2 at intersection positions of c rows of light-emitting units 2 arranged sequentially along the first direction Y and b columns of light-emitting units 2 arranged sequentially along the second direction X in the first array, and d light-emitting units 2 adjacent to the c×b light-emitting units 2 along the second direction X; where 0<c<a, c×b<m, c×b+d=m, so that each driving member 3 in the second region 103 is electrically connected to the c×b light-emitting units 2 at the intersection positions of the c rows of light-emitting units 2 and the b columns of light-emitting units 2 in the first array, and then, is electrically connected to the d light-emitting units 2 adjacent to the c×b light-emitting units 2 along the second direction X through the remaining (m−c×b) channels of the driving member 3, and therefore, the m channels of each of at least some driving members 3 in the second region 103 can be fully utilized, the number of the driving members 3 in the second region 103 is reduced, and the cost of the light-emitting backplane is reduced. Further, the scheme of fully utilizing all the channels of each of at least some driving member 3 in the second region 103 only needs to reduce the number of the driving members 3, has little influence on the process for manufacturing the light-emitting backplane, and does not influence the reliability of the light-emitting backplane.

In a second aspect, an embodiment of the present disclosure further provides a display apparatus. FIG. 5 is a schematic cross-sectional diagram of a structure of a display apparatus according to an embodiment of the present disclosure. Referring to FIG. 5, the display apparatus includes the light-emitting backplane 17 in the above embodiments.

The light-emitting backplane 17 may be configured to directly display pictures or video.

In some embodiments, the display apparatus further includes a liquid crystal screen 18, and the light-emitting backplane 17 is located on a back side of the liquid crystal screen 18, and is configured to provide backlight for the liquid crystal screen 18.

The light-emitting backplane 17 may provide direct-type backlight for the liquid crystal screen 18, and liquid crystals in the liquid crystal screen 18 are rotated under the action of an electric field, so that the display of the pictures or video of the display apparatus is realized.

By adopting the light-emitting backplane in the above embodiments, the cost of the display apparatus is reduced, and the reliability of the display apparatus is improved.

The display apparatus provided by the embodiment of the present disclosure may be any product or component with a display function, such as a mini-LED panel, a mini-LED television, a mini-LED billboard, an LED panel, an LED television, an LED billboard, an LCD panel, an LCD television, an LCD billboard, a display, a mobile phone, a navigator or the like.

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. A light-emitting backplane, comprising a display region and a binding side border region on one side of the display region, wherein the display region comprises a first region and a second region sequentially arranged along a first direction away from the binding side border region;
wherein the light-emitting backplane comprises:
a substrate, a plurality of light-emitting units, wherein the plurality of light-emitting units are located on one side of the substrate, and are arranged in a first array along the first direction and a second direction; and
a plurality of driving members located on the side of the substrate where the plurality of light-emitting units are located, wherein the plurality of driving members are arranged in a second array along the first direction and the second direction;
wherein the first direction and the second direction intersect with each other;
orthographic projections of the first array and the second array on the substrate do not overlap with each other;
each of the plurality of driving members comprises m channels, in the first region, each driving member is electrically connected to m light-emitting units at intersection positions of a rows of light-emitting units sequentially arranged along the first direction and b columns of light-emitting units sequentially arranged along the second direction in the first array, and each driving member is electrically connected to different light-emitting units;
in the second region, a total number of rows of light-emitting units in the first array arranged along the first direction is c, and each of at least some driving members is electrically connected to c×b light-emitting units at intersection positions of c rows of light-emitting units arranged sequentially along the first direction and b columns of light-emitting units arranged sequentially along the second direction in the first array, and d light-emitting units adjacent to the c×b light-emitting units along the second direction; and
0<c<a, c×b<m, c×b+d=m, a>1, b>0, m>1, 0<d<m, and a, b, c, d, and m are integers.

2. The light-emitting backplane of claim 1, further comprising a plurality of first wiring lines and a plurality of groups of second wiring lines, which are located on the side of the substrate where the plurality of light-emitting units are located and located on a side of the plurality of light-emitting units and the plurality of driving members close to the substrate; wherein
the plurality of first wiring lines and the plurality of groups of second wiring lines are arranged in a same layer;
the plurality of first wiring lines are sequentially arranged along the second direction, and extend along the first direction;
the plurality of first wiring lines are electrically connected to the plurality of columns of the light-emitting units sequentially arranged along the second direction in the first array in one-to-one correspondence;
the plurality of groups of second wiring lines are sequentially arranged along the second direction, and each group of second wiring lines extend along the first direction, and
the plurality of groups of second wiring lines are electrically connected to the plurality of columns of the driving members sequentially arranged along the second direction in the second array in one-to-one correspondence.

3. The light-emitting backplane of claim 2, wherein a=m and b=1.

4. The light-emitting backplane of claim 2, wherein a>1 and b>1.

5. The light-emitting backplane of claim 3, wherein one of the plurality of first wiring lines electrically connected to the light-emitting units in a same column and one of the plurality of groups of second wiring lines electrically connected to the driving members in a column are located on two opposite sides of the light-emitting units in the column along the second direction, respectively;
an orthographic projection of each driving member on the substrate is located between orthographic projections of the two light-emitting units adjacent to the driving member along the first direction on the substrate;
the m channels are electrically connected to different light-emitting units through different first connecting lines, respectively, and
the first connecting lines, the plurality of first wiring lines and the plurality of groups of second wiring lines are arranged in the same layer, and orthographic projections of the first connecting lines, the plurality of first wiring lines and the plurality of groups of second wiring lines on the substrate do not overlap with each other; and
wherein the plurality of first wiring lines and the plurality of groups of second wiring lines are arranged alternately in sequence along the second direction.

6. (canceled)

7. The light-emitting backplane of claim 4, wherein any one column of the plurality of columns of the driving members sequentially arranged along the second direction is located between two columns of light-emitting units sequentially arranged along the second direction adjacent to the any one column of the driving members;
the m channels are electrically connected to different light-emitting units through different first connecting lines, respectively; and
the first connecting lines are located on a side of the plurality of first wiring lines and the plurality of groups of second wiring lines away from the substrate, and on a side of the plurality of light-emitting units and the plurality of driving members close to the substrate, and orthographic projections of the first connecting lines, the plurality of first wiring lines and the plurality of groups of second wiring lines on the substrate at least partially overlap with each other; and
wherein any one group of second wiring lines is located between two first wiring lines adjacent to the any one group of second wiring lines along the second direction, and
orthographic projections of the first wiring line and the corresponding column of light-emitting units electrically connected to the first wiring line on the substrate at least partially overlap with each other.

8. (canceled)

9. The light-emitting backplane of claim 5, wherein in the second region, the first connecting lines extend from the respective channels of each driving member to one side of the second region away from the first region and are electrically connected to the corresponding light-emitting units; and
orthographic projections of the first connecting lines on the substrate do not overlap with each other.

10. The light-emitting backplane of claim 3, wherein in the second region, an orthographic projection of each driving member on the substrate is located between orthographic projections of the two light-emitting units adjacent to the driving member along the second direction on the substrate; and
in the second region, along a direction that the m light-emitting units electrically connected to each driving member are arranged,
m is an even number and an orthographic projection of each driving member on the substrate is located between orthographic projections of an (m/2)-th light-emitting unit and an (m/2+1)-th light-emitting unit on the substrate; or
m is an odd number, and an orthographic projection of each driving member on the substrate is located between orthographic projections of an (m−1/2-th light-emitting unit and an (m−1/2−1)-the light-emitting unit on the substrate.

11. (canceled)

12. The light-emitting backplane of claim 4, wherein in the second region, for the c×b light-emitting units at the intersection positions of the c rows of light-emitting units and the b columns of light-emitting units in the first array electrically connected to each driving member,
b is an even number, and an orthographic projection of each driving member on the substrate is located between orthographic projections of a (b/2)-th column of light-emitting units and a (b/2+1)-th column of light-emitting units on the substrate, or
b is an odd number, and the orthographic projection of each driving member on the substrate is located between orthographic projections of a ((b−1)/2)-th column of light-emitting units and a ((b−1)/2+1)-th column of light-emitting units on the substrate.

13. The light-emitting backplane of claim 5, wherein each driving member further comprises a body electrically connected to the channels;
in the first region, the channels are located on a side of the body close to a corresponding light-emitting unit electrically connected to the driving member, and a corresponding group of second wiring lines is located on a side of the body away from the light-emitting unit electrically connected to the driving member;
the first connecting lines extend from the respective channels of the driving member to be electrically connected to the light-emitting units; and
orthographic projections of the first connecting lines on the substrate do not overlap with each other.

14. The light-emitting backplane of claim 3, wherein in the first region,
m is an even number, and an orthographic projection of each driving member on the substrate is located between orthographic projections of an (m/2)-th light-emitting unit and an (m/2+1)-th light-emitting unit electrically connected to the driving member on the substrate; or
m is an odd number, and an orthographic projection of each driving member on the substrate is located between orthographic projections of an ((m−1)/2)-th light-emitting unit and an ((m−1)/2+1)-th light-emitting unit electrically connected to the driving member on the substrate.

15. The light-emitting backplane of claim 4, wherein in the first region,
b is an even number, and an orthographic projection of each driving member on the substrate is located between orthographic projections of a (b/2)-th column of light-emitting units and a (b/2+1)-th column of light-emitting units electrically connected to the driving member on the substrate; or
b is an odd number, and an orthographic projection of each driving member on the substrate is located between orthographic projections of a ((b−1)/2)-th column of light-emitting units and a ((b−1)/2+1)-th column of light-emitting units electrically connected to the driving member on the substrate; and
wherein in the first region,
a is an even number and an orthographic projection of each driving member on the substrate is located between orthographic projections of an (a/2)-th row of light-emitting units and an (a/2+1)-th row of light-emitting units electrically connected to the driving member on the substrate; or
a is an odd number, and an orthographic projection of each driving member on the substrate is located between orthographic projections of an (a−1)/2)-th row of light-emitting units and an (a−1/2−1)-th row of light-emitting units electrically connected to the driving member on the substrate.

16. (canceled)

17. The light-emitting backplane of claim 3, wherein in the second region, at least one driving member is electrically connected to e light-emitting units sequentially arranged along the first direction and f light-emitting units adjacent to the e light-emitting units along the second direction; and
e+f<m, 0<<m, 0≤f<m, and e and f are integers.

18. The light-emitting backplane of claim 4, wherein in the second region, at least one driving member is electrically connected to the c×b light-emitting units at the intersection positions of the c rows of light-emitting units arranged sequentially in the first direction and the b columns of light-emitting units arranged sequentially in the second direction in the first array and g light-emitting units adjacent to the c×b light-emitting units in the second direction; and
c×b+g<m, 0≤g<m and g is an integer.

19. The light-emitting backplane of claim 13, wherein each group of second wiring lines comprise a power signal line, a ground signal line, a data line, a control signal input line, and a control signal output line;
the power signal line, the data line, the control signal input line, the ground signal line, and the control signal output line are sequentially arranged along the second direction;
each driving member comprises m channel output terminals, two power signal terminals, two ground signal terminals, two data signal terminals, a control signal input terminal and a control signal output terminal;
the m channel output terminals are electrically connected to m first connecting lines in one-to-one correspondence, respectively;
the power signal line is electrically connected to the two power signal terminals of each of a column of driving members;
the data line is electrically connected to the two data signal terminals of each of the column of driving members;
the ground signal line is electrically connected to the two ground signal terminals of each of the column of driving members; and
along the first direction, a control signal input terminal of a first driving member farther from the binding side border region is electrically connected to a control signal output terminal of a second driving member adjacent to the first driving member and closer to the binding side border region, the control signal input terminal of the driving member closest to the binding side border region is electrically connected to the control signal input line, and the control signal output terminal of the driving member farthest from the binding side border region is electrically connected to the control signal output line; and
wherein the m channel output terminals are sequentially arranged at a first end of the body:
the two power signal terminals, the two ground signal terminals and the two data signal terminals are symmetrically distributed a second end and a third end of the body, which are opposite to each other, and
the control signal input termina and the control signal output terminal are respectively located at the second end and the third end of the body which are opposite to each other.

20. (canceled)

21. The light-emitting backplane of claim &Z, wherein each group of second wiring lines comprise a power signal line, b ground signal lines, a data line, a control signal input line, and a control signal output line;
the b ground signal lines are located on two opposite sides of a column of driving members electrically connected to the b ground signal lines in the second direction, each ground signal line corresponds to a column of light-emitting units, and an orthographic projection of the ground signal line on the substrate at least partially overlaps with an orthographic projection of the column of light-emitting units on the substrate, and
the power signal line, the data line, the control signal input line, and the control signal output line are located between two adjacent ground signal lines; and
each driving member comprises m channel output terminals, a power signal terminal, b ground signal terminals, a data signal terminal, a control signal input terminal and a control signal output terminal;
the m channel output terminals are electrically connected to m first connecting lines in one-to-one correspondence, respectively;
the power signal line is electrically connected to the power signal terminal of each of a column of driving members;
the data line is electrically connected to the data signal terminal of each of the column of driving members,
the b ground signal lines are electrically connected to the b ground signal terminals of each of the column of driving members in one-to-one correspondence, respectively: and
along the first direction, a control signal input terminal of a first driving member farther from the binding side border region is electrically connected to a control signal output terminal of a second driving member adjacent to the first driving member and closer to the binding side border region, the control signal input terminal of the driving member closest to the binding side border region is electrically connected to the control signal input line, and the control signal output terminal of the driving member farthest from the binding side border region is electrically connected to the control signal output line.

22. (canceled)

23. The light-emitting backplane of claim 1, wherein each driving member further comprises a body electrically connected to the channels;
the m channel output terminals and the power signal terminal are arranged at a first end of the body;
the b ground signal terminals, the data signal terminal, the control signal input terminal and the control signal output terminal are arranged at a second end of the body, and
the first end and the second end are opposite to each other.

24. The light-emitting backplane of claim 21, further comprising an insulating layer between a layer where the first connecting lines are located and a layer where the plurality of first wiring lines and the plurality of groups of second wiring lines are located;
each first connecting line is electrically connected to the corresponding first wiring line through a first via in the insulating layer;
the power signal terminals of each column of the driving members are electrically connected to the corresponding power signal line through a second connecting line and a second via in the insulating layer;
the data signal terminals of each column of driving members are electrically connected to the corresponding data line through a third connecting line and a third via in the insulating layer;
b=2, and one ground signal terminal of each driving member in each column of driving members is electrically connected to one ground signal line through two fourth connecting lines, one adapter line and at least one fourth via in the insulating layer;
the other ground signal terminal of each driving member in each column of driving members is electrically connected to the other ground signal line through a fifth connecting line and a fifth via in the insulating layer;
along the first direction, a control signal input terminal of a first driving member farther from the binding side border region and a control signal output terminal of a second driving member adjacent to the first driving member and closer to the binding side border region are electrically connected to an intermediate connecting line through a sixth connecting line and a sixth via in the insulating layer, respectively, the control signal input terminal of the driving member closest to the binding side border region is electrically connected to the control signal input line through a seventh connecting line and a seventh via in the insulating layer, and the control signal output terminal of the driving member farthest from the binding side border region is electrically connected to the control signal output line through an eighth connecting line and an eighth via in the insulating layer;
the second connecting line, the third connecting line, the fourth connecting line, the fifth connecting line, the sixth connecting line, the seventh connecting line and the eighth connecting line are arranged in a same layer as the first connecting lines, and
the adapter line and the intermediate connecting line are arranged in a same layer as the plurality of first wiring lines and the plurality of groups of second wiring lines.

25. The light-emitting backplane of claim 19, wherein a line width of each of the ground signal line and the plurality of first wiring lines is greater than that of the power signal line; and
the line width of the power signal line is greater than that of each of the data line, the control signal input line, and the control signal output line, and
the power signal line, the ground signal line, the data line, the control signal input line and the control signal output line extend from the display region to the binding side border region, and
the plurality of first wiring lines extend from the display region to the binding side border region.

26-28. (canceled)

29. A display apparatus, comprising the light-emitting backplane of claim 1.

30. (canceled)
